(19) United States
(12) Patent Application Publication
(10) Pub. No.: US 2009/0194861 A1
(43) Pub. Date: Aug. 6, 2009

(54) Hermetically-packaged devices, and methods for hermetically packaging at least one device at the wafer level

(76) Inventors: Mathias Bonse, Santa Rosa, CA (US); Eric Ehlers, Santa Rosa, CA (US); Alan Kashiwagi, Sebastopol, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 12/012,589

(22) Filed: Feb. 4, 2008

(51) Int. Cl. H01L 21/50; H01L 23/48

(52) U.S. Cl. 257/690; 438/118; 257/E21.499; 257/E23.01

(57) ABSTRACT

A plurality of devices are hermetically packaged at the wafer level by 1) providing a substrate wafer having a plurality of at least partially-formed devices thereon; 2) forming separation walls on the substrate wafer, around different ones of the at least partially-formed devices; and 3) wafer bonding a cap wafer to the separation walls, to form a plurality of hermetic packages.

### BACKGROUND

Radio frequency (RF) integrated circuits (ICs) are typically packaged in discrete form (i.e., individually, after they have been diced from a wafer). Some exemplary types of packages that are used for discrete packaging are plastic injection molded packages and ceramic cavity packages. Usually, there is a correlation between the price and performance of the different types of packages (and packaging processes), with higher-frequency or hermetic packages and processes costing more than lower-frequency or non-hermetic packages and processes.

Packaging ICs in discrete form is labor intensive, and thus expensive. In addition, the discrete packaging of fragile devices, such as Micro-Electro-Mechanical-System (MEMS) based switches, can lead to damage, loss and a resultant low yield of functioning packaged devices. Thus, discrete packaging methods (and packages) are typically not suitable for packaging fragile devices.

Wafer-level packaging using wafer bonding has been suggested in the past, but it is generally difficult to create electrical connections to the components that are enclosed within the package. For example, signals carried on signal lines passing underneath conductive metal seals can suffer from degradation and loss; and, while signal quality can be improved by using non-metal seals, it is difficult to create hermetically-sealed packages using non-metal seals.

As disclosed in United States Patent Application Publication 2006/0175707 A1, connection holes may be formed in a cap wafer, and conductive connection rods may be formed in the connection holes for the purpose of making electrical connections to a device contained within a package formed between the cap wafer and a device wafer. However, this method requires relatively complex processing of the cap wafer, as well as alignment of the cap wafer and device wafer.

### BRIEF DESCRIPTION OF THE DRAWINGS

Illustrative embodiments of the invention are illustrated in the drawings, in which:

FIG. 1 illustrates an exemplary method for hermetically packaging at least one device at the wafer level;

FIGS. 2 & 5 illustrate exemplary plan views of a substrate wafer that is operated on by the method shown in FIG. 1; and

FIGS. 3, 4 and 6-13 illustrate exemplary cross-sections of the substrate wafer shown in FIGS. 2 & 5, and the processing thereof in accord with the method shown in FIG. 1.

### DETAILED DESCRIPTION

As a preliminary manner, it is noted that, in the following description, like reference numbers appearing in different drawing figures refer to like elements/features.

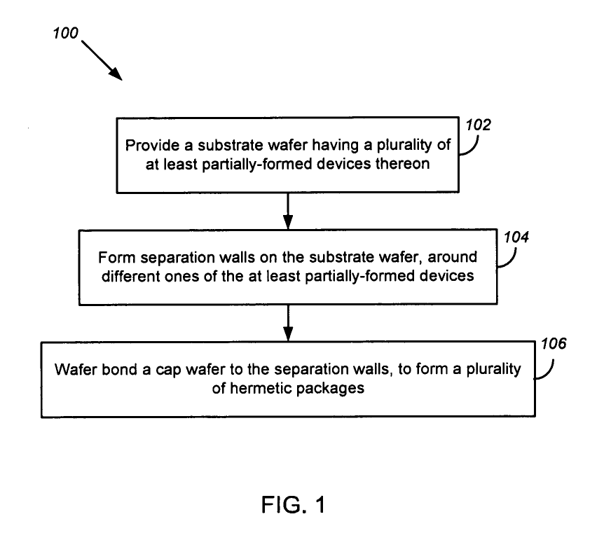

FIG. 1 illustrates an exemplary method 100 for hermetically packaging a plurality of devices at the wafer level. The method 100 begins with the provision of a substrate wafer having a plurality of at least partially-formed devices thereon (at block 102). “Providing” the substrate wafer may comprise, for example, one or more of: forming, obtaining or positioning the substrate wafer.

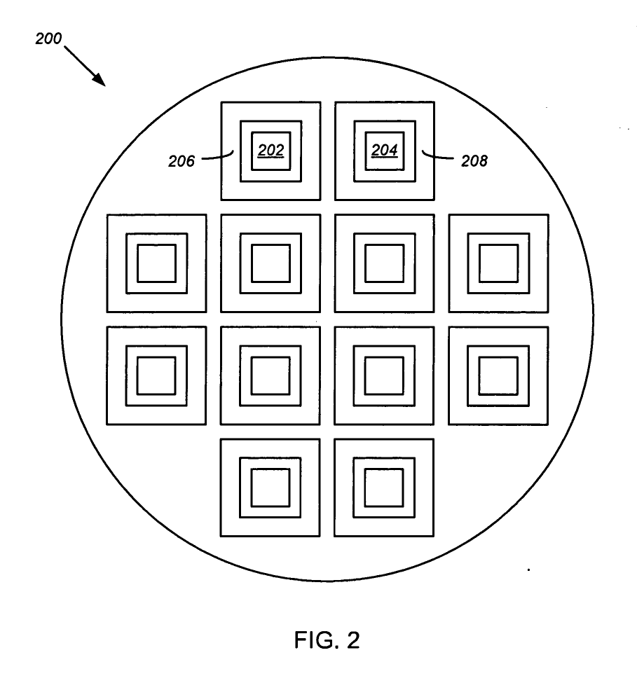

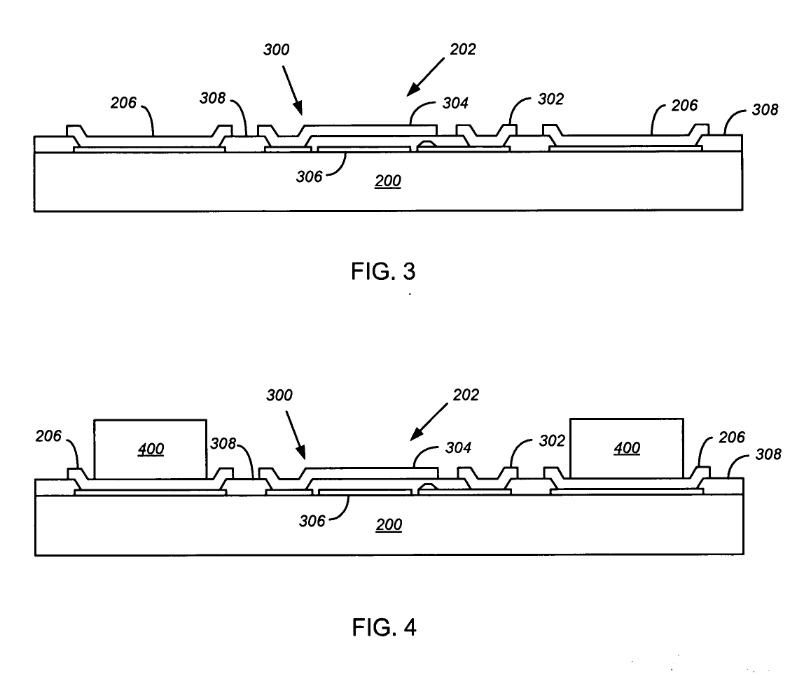

A plan view of an exemplary substrate wafer 200 is shown in FIG. 2, and a cross-section of one of the at least partially-formed devices 202 on the substrate wafer 200 is shown in FIG. 3. By way of example, each of the “devices” on the substrate wafer 200 may take the form of a Micro-Electro-Mechanical-System (MEMS), integrated circuit (IC) or other micro-electronic device. As used herein, the word “device” is meant to include both a single component, such as a transistor or resistor, or a group of components that perform one or more cooperative or individual functions. An example of a group of components performing a cooperative function is a group of components defining a single MEMS. An example of a group of components performing individual functions is a group of components defining two independently operable MEMS.

As used herein, an “at least partially-formed device” 202, 204 is meant to include both 1) a device having components that are fully-formed and operational on a side of the substrate wafer 200 that is to be hermetically packaged (regardless of whether connections to the device have been formed on an opposing (or non-packaged) side of the wafer), and 2) a device having components that are only partially-formed or not yet operational on the side of the substrate wafer that is to be hermetically packaged. This includes, for example, a device such as a MEMS that is fully-formed, but for completion of a MEMS release process.

After providing the substrate wafer (at block 102), the method 100 continues with the formation of separation walls on the substrate wafer (at block 104). The separation walls 400, 500 are formed around different ones of the at least partially-formed devices 202, 204, as shown in FIGS. 4 & 5. Typically, a separation wall 400, 500 will be formed around each of the devices 202, 204 on a substrate wafer 200, although this need not be the case.

After forming the separation walls 400, 500, a cap wafer is wafer bonded to the separation walls (at block 106). In one embodiment, the cap wafer may be wafer bonded to the separation walls by melting eutectic solder on at least one of: the separation walls, and the cap wafer. That is, prior to wafer bonding, the eutectic solder may reside on or in the separation walls, on the cap wafer, or on both the separation walls and the cap wafer. The eutectic solder may be melted by one or both of heat and pressure. In another embodiment, the cap wafer may be wafer bonded to the separation walls via a thermo-compression bond that is formed, for example, by heating and compressing pure gold on at least one of: the separation walls, and the cap wafer. In yet another embodiment, the cap wafer may be wafer bonded to the separation walls via an anodic bond that is formed, for example, by heating the cap wafer and separation walls, and by applying a high electric field between the cap wafer and the separation walls (which is usually done by applying a high electric field between the cap wafer and the substrate wafer). Typically, an anodic bond is formed between non-conductive materials, such as materials (a cap wafer and separation walls) comprised of or containing glass. An exemplary wafer bond between a cap wafer 900 and a separation wall 400 is shown in FIG. 9.

By means of the method 100, a plurality of hermetic packages is formed.

The method 100, and variants thereof, will now be described in further detail with respect to the exemplary process steps and apparatus shown in FIGS. 2-13.

FIG. 2 shows a plan view of an exemplary substrate wafer 200 having a plurality of partially-formed devices, such as partially-formed devices 202 and 204, thereon. The substrate wafer 200 may take various forms, including that of a gallium arsenide (GaAs), silicon (Si) or sapphire wafer. Optionally, a grid of landing pads 206, 208 may be formed on the substrate wafer 200, such that each landing pad 206, 208 surrounds a respective one of the partially-formed devices 202, 204. In some embodiments, the individual landing pads 206, 208 shown in FIG. 2 may be replaced with a landing grid, wherein adjacent ones of the partially-formed devices 202, 204 share a portion of the landing grid that runs between them. By way of example, the landing pads 206, 208 or landing grid may comprise structural gold pads formed on layers of titanium, platinum and gold.

FIG. 3 shows a cross-section of one of the partially-formed devices 202. By way of example, the partially-formed device 202 is a MEMS relay 300 having a stationary electrode 302, a cantilevered electrode 304, and an actuation electrode 306. In one embodiment, the electrodes 302, 304, 306 may comprise structural gold components formed on layers of titanium, platinum and gold. In use, the application of a control signal to electrode 306 causes cantilevered electrode 304 to contact stationary electrode 302, thereby forming a conductive path between electrodes 302 and 304. The MEMS relay 300 is considered partially-formed because the cantilevered electrode 304 is incapable of moving due to the presence of a sacrificial resist 308.

It is noted that the partially-formed MEMS relay 300 shown in FIGS. 3, 4 and 7-13 is exemplary only. Alternately, the partially-formed MEMS relay 300 could be replaced with another fully-formed or partially-formed device, without substantially affecting the manner in which the method 100 is performed. The partially-formed MEMS relay 300 could also be replaced with another type of MEMS, an IC, or some other form of micro-electronic device.

FIG. 4 shows a cross-section of a separation wall 400 formed around the MEMS relay 300. As shown, the separation wall 400 may be formed on the optional landing pad 206. However, if the optional landing pad 206 is not present, the separation wall 400 may be formed directly on the substrate wafer 200. FIG. 5 shows that a plurality of separation walls 400, 500 may be formed around different ones of the partially-formed devices 202, 204. In some embodiments, a separation wall may be formed around each of the partially-formed devices 202, 204. In other embodiments, separation walls may only be formed around some of the partially-formed devices 202, 204. Alternately, a connected grid of separation walls could be formed, such that adjacent ones of the partially-formed devices 202, 204 share a common separation wall.

The separation walls 400, 500 may be formed in various ways, some of which will be described in detail below.

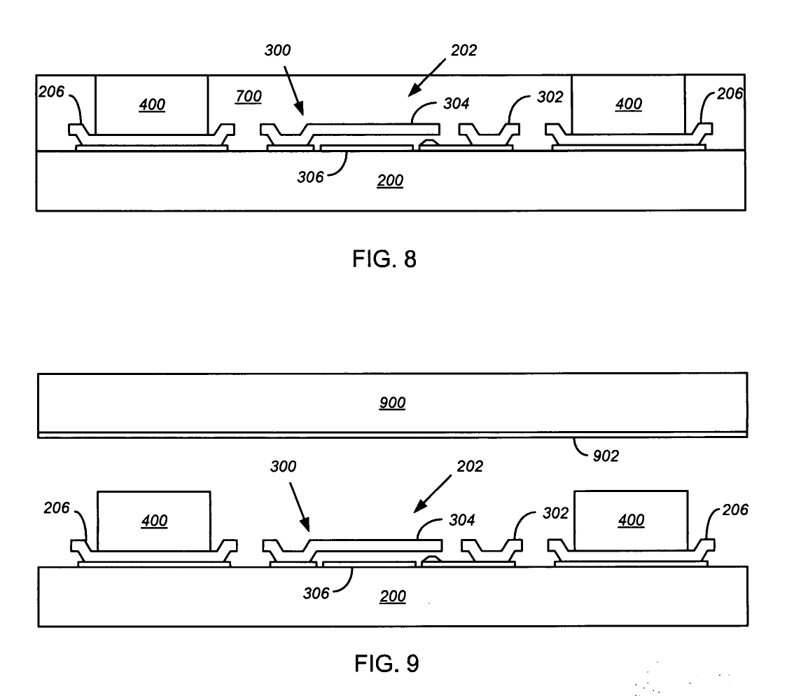

In some embodiments, the separation walls 400, 500 may be formed by applying and patterning a photoresist 700 on the surface of the substrate wafer 200 on which the at least partially-formed device 202 thereon. See, FIG. 7. The patterning of the photoresist 700 exposes areas of the substrate wafer 200 (i.e., the landing pads 206, 208) on which the separation walls 400, 500 are to be formed. The separation walls 400, 500 may then be formed by plating the exposed areas of the substrate wafer 200 (FIG. 8), and the photoresist 700 may subsequently be removed (FIGS. 4 & 5). In some embodiments, the plating process may be an electroplating process.

In other embodiments, the separation walls 400, 500 may be formed by applying and patterning a photoresist 700 on the surface of the substrate wafer 200 on which the at least partially-formed devices 202 thereon. See, FIG. 7. Again, the patterning of the photoresist 700 exposes areas of the substrate wafer 200 on which the separation walls 400, 500 are to be formed. The separation walls 400, 500 may then be formed by physical vapor deposition, and the photoresist 700 may be subsequently removed. In this embodiment, removal of the photoresist 700 causes material that was deposited on the photoresist 700 during formation of the separation walls 400, 500 to be lifted off with the photoresist 700.

Exemplary compositions of the separation walls 400, 500 will be discussed later in this description.

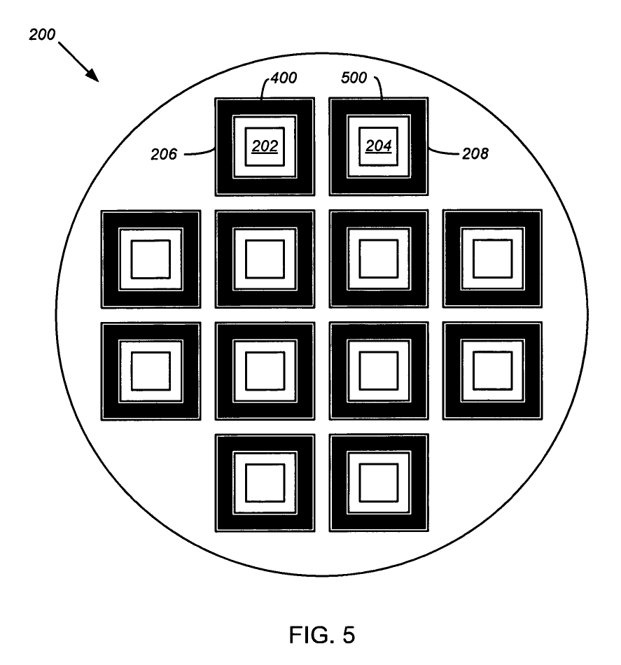

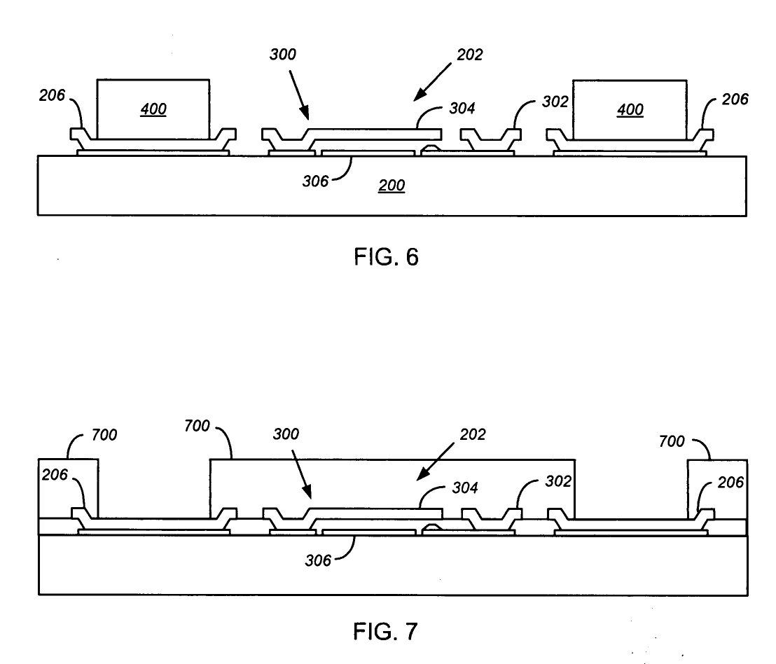

Following formation of the separation wall 400, 500 the formation of any partially-formed devices 202 may be finished, as necessary. As shown in FIG. 6, and by way of example, further processing of partially-formed devices 202 may comprise performing a MEMS release process (e.g., a process to remove the sacrificial resist 308).

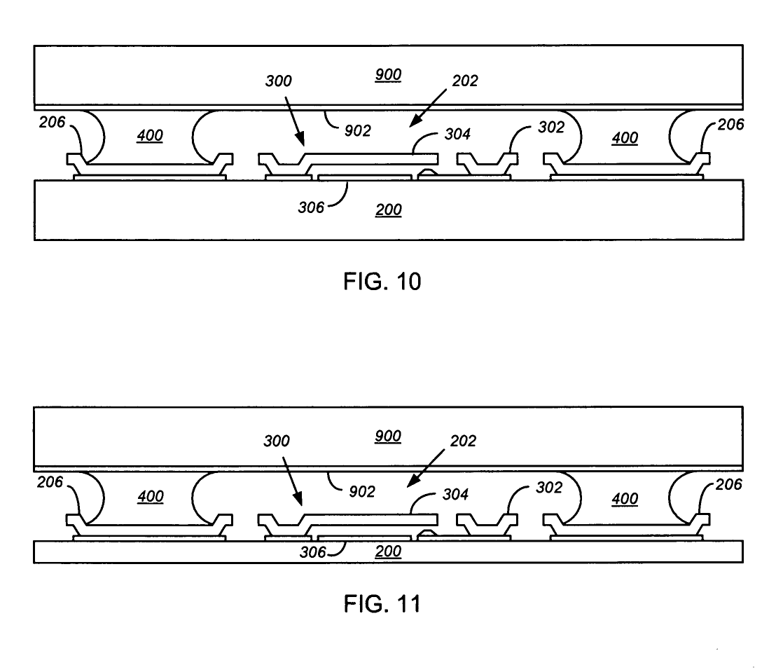

FIGS. 9 & 10 show the positioning of a cap wafer 900 over the substrate wafer 200 (FIG. 9) and on the separation wall 400 (FIG. 10). The cap wafer 900 has no vias therein for connecting to the MEMS relay 300 (or to an alternate device). As a result, precise alignment of the cap wafer 900 with the substrate wafer 200 is unnecessary. That is, the cap wafer 900 may be rotated with respect to the substrate wafer 200, or somewhat offset with respect to the substrate wafer 200, without affecting the hermetic packaging or functionality of the MEMS relay 300 (or other device). Preferably, the cap wafer 900 is also free of any indentations in a surface of the wafer facing the device 300 (or at least free of any indentations that need to be aligned with the device 300, or other devices, on the substrate wafer 200).

The cap wafer 900 and substrate wafer 200 may be formed of the same or different materials. For example, the cap wafer 900 may be a gallium arsenide (GaAs), silicon (Si) or sapphire wafer. Or, in some embodiments, the cap wafer 900 may be formed of a translucent or transparent material, such as glass.

After positioning the cap wafer 900 on the separation walls 400, 500, the cap wafer 900 is wafer bonded to the separation walls 400, 500. See, FIG. 10. In one embodiment, the cap wafer is bonded to the separation walls by melting eutectic solder. As previously mentioned, prior to positioning the cap wafer 900 on the separation walls 400, 500, the eutectic solder may be on or in the separation walls 400, 500, on the cap wafer 900, or on both the separation walls 400, 500 and the cap wafer 900.

In some embodiments, the separation walls 400, 500 may be formed of eutectic solder, such as a mixture of gold and tin (AuSn), a mixture of gold and indium (AuIn), or a mixture of indium and tin (InSn). Additionally, or alternately, the cap wafer 900 may be coated with eutectic solder. In yet other embodiments, and in lieu of the cap wafer 900 being coated with eutectic solder, eutectic solder may be applied to the cap wafer 900 in a pattern that mirrors the pattern of the separation walls 400, 500 on the substrate wafer 200 (see FIG. 5). This is especially useful if the cap wafer 900 is translucent or transparent, and if visibility of packaged devices is desired. If the eutectic solder is applied to the cap wafer 900 in a pattern that mirrors the pattern of the separation walls 400, 500, the eutectic solder may be applied in a pattern that “loosely” mirrors the pattern of the separation walls 400, 500, so that precise alignment of the cap and substrate wafers 900, 200 is unnecessary.

In one useful embodiment, the separation walls 400, 500 are formed by a mixture of Au and Sn, mixed in a ratio of 80/20 (by weight). In another useful embodiment, the separation walls 400, 500 are formed of a thicker lower layer of gold, capped by a thinner upper layer of AuSn. In other useful embodiments, the separation walls 400, 500 may be formed of any of the following mixtures:

80% Au/20% Sn;

100% In;

97% In/3% Ag (silver); or

58% Bi (bismuth)/42% Sn

The above exemplary compositions of the separation walls 400, 500 are not limiting or all-inclusive.

With the above compositions of the separation walls 400, 500, the cap wafer 900 may be coated with an adhesion layer 902 (FIGS. 9-13) comprised of, for example:

Ni (nickel)/Au;

Ti (titanium)/Pt (platinum)/Au;

Ti/Au; or

Cr (chromium)/Au

Alternately, the cap wafer 900 may be coated with eutectic solder. In some embodiments, this may be done by sputter deposition.

The bonding of the cap and substrate wafers 900, 200 may be achieved, for example, by a process that employs one or more of: heating part or all of the structure shown in FIG. 10; pressing the cap and substrate wafers 900, 200 toward one another; or running an electrical current across the to-be-bonded interface (in the case of anodic bonding). In this manner, eutectic solder or gold, for example, can be caused to melt and seal the MEMS relay 300 (or other device) within a hermetic package; or, for example, a chemical bond may be formed between non-conductive bonding surfaces, such as glass surfaces. In some environments, it may be desirable to dry etch (or H₂ plasma etch) oxides on eutectic solder, just before wafer bonding is performed.

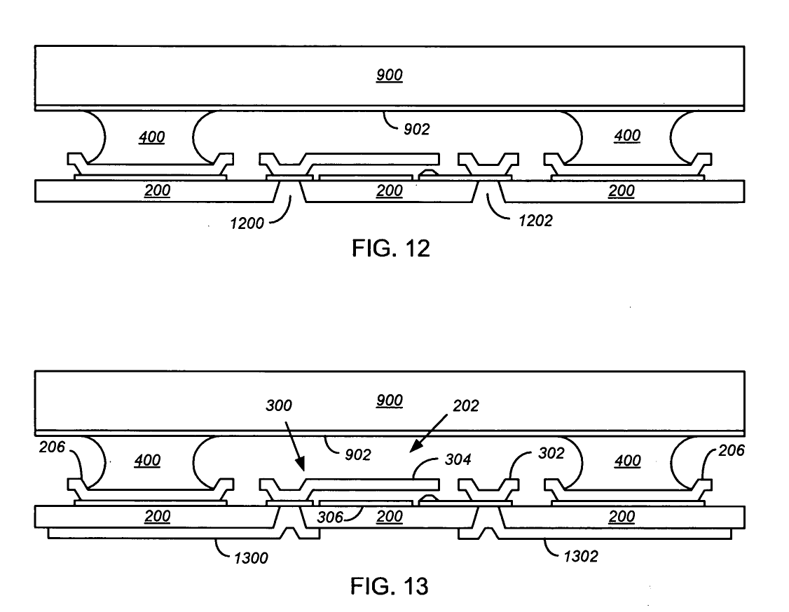

After wafer bonding the cap and substrate wafers 900, 200, the substrate wafer 200 may optionally be thinned, as shown in FIG. 11. Thereafter, through-wafer vias 1200, 1202 may be formed in the substrate wafer 200. See, FIG. 12. The through-wafer vias 1200, 1202 are positioned to coincide with the electrodes 302, 304 of the various devices that are packaged between the cap and substrate wafers 900, 200. Subsequently, a metallization pattern 1300, 1302 may be formed on a surface of the substrate wafer 200 opposite the surface on which the packaged devices are formed. See, FIG. 13. The metallization pattern 1300, 1302 provides electrical connections to the electrodes 302, 304 of the devices 300, by means of the through-wafer vias 1200, 1202 in the substrate wafer 200.

An exemplary way to form the through-wafer vias 1200, 1202 and metallization 1300, 1302 shown in FIGS. 12 & 13 is described in the U.S. patent application of Ehlers, et al. titled “Through-Chip Via Interconnects for Stacked Integrated Circuit Structures” (Ser. No. 11/847,239, filed Aug. 29, 2007).

After hermetically packaging a plurality of devices 202, 204 on a wafer 200, and forming through-wafer vias 1200, 1202 and metallization 1300, 1302 to route signals between the devices 202, 204 and the external world, the hermetically packaged devices may be separated from each other. In some embodiments, this may be done by sawing.

Depending upon the particular implementation of the method 100 (FIG. 1), the method 100 can provide one or more advantages over other wafer-level packaging methods. For example, the method 100 can improve frequency performance of a device (that is, with respect to discrete packaging of the device). The method 100 can also package devices at a lower cost compared to many discrete packaging methods, partly because the method 100 packages devices in parallel and with less parts handling. Lower cost is also achieved as a result of not having to submit the cap wafer to complex processing steps, and because the cap wafer does not have to be carefully aligned with the substrate wafer. Further, the method 100 provides hermeticity, through a metal bond between a cap wafer and a substrate wafer.

What is claimed is:

1. A method for hermetically packaging a plurality of devices at a wafer level, comprising:
providing a substrate wafer having a plurality of at least partially-formed devices thereon;
forming separation walls on the substrate wafer, around different ones of the at least partially-formed devices; and
wafer bonding a cap wafer to the separation walls, to form a plurality of hermetic packages.

2. The method of claim 1, wherein forming the separation walls comprises:
applying and patterning a photoresist over a surface of the substrate wafer having the at least partially-formed devices thereon, the patterning of the photoresist exposing areas of the substrate wafer on which the separation walls are to be formed;
forming the separation walls by at least one of: plating the exposed areas of the substrate wafer, and physical vapor deposition; and
removing the photoresist.

3. The method of claim 1, wherein the at least partially-formed devices comprise at least one partially-formed device, the method further comprising:
finishing the formation of the at least one partially-formed device after forming the separation walls.

4. The method of claim 3, wherein finishing the formation of the at least one partially-formed device comprises performing a MEMS release process.

5. The method of claim 1, further comprising, thinning the substrate wafer after performing the wafer bonding.

6. The method of claim 5, further comprising, forming through-wafer vias in the substrate wafer, the through-wafer vias being positioned to coincide with electrodes of the at least partially-formed devices.

7. The method of claim 6, further comprising, forming a metallization pattern on a surface of the substrate wafer that is opposite a surface of the substrate wafer on which the at least partially-formed devices are on, the metallization pattern being electrically connected to the electrodes by the through-wafer vias in the substrate wafer.

8. The method of claim 1, wherein the cap wafer is bonded to the separation walls by melting eutectic solder on at least one of the separation walls and the cap wafer.

9. The method of claim 8, wherein the separation walls are formed by the eutectic solder.

10. The method of claim 8, further comprising, prior to wafer bonding, forming an adhesion layer on a surface of the cap wafer facing the at least partially-formed devices.

11. The method of claim 1, wherein the at least partially-formed devices comprise at least one of: at least one partially-formed MicroElectroMechanical System (MEMS), and at least one partially-formed integrated circuit (IC).

12. The method of claim 1, wherein bonding the cap wafer to the separation walls comprises at least one of: thermo-compression bonding the cap wafer to the separation walls, and anodic bonding the cap wafer to the separation walls.

13. Apparatus, comprising:
a substrate wafer having i) a plurality of devices formed thereon, and ii) a plurality of through-wafer vias positioned to coincide with electrodes of the devices;
a plurality of separation walls on the substrate wafer, the separation walls being formed around the devices, to separate some of the devices from others of the devices; and
a cap wafer, wafer-bonded to the separation walls on the substrate wafer, to hermetically seal the devices between the substrate wafer and the cap wafer, the cap wafer having no vias therein for connecting to the devices.

14. The apparatus of claim 13, wherein the cap wafer has no indentations in a surface of the wafer facing the plurality of devices.

15. The apparatus of claim 13, wherein the cap wafer is wafer-bonded to the separation walls via eutectic solder.

16. The apparatus of claim 15, wherein the cap wafer is covered with at least one of: the eutectic solder, and an adhesion layer.

17. The apparatus of claim 15, wherein the separation walls are formed of eutectic solder.

18. The apparatus of claim 13, wherein the substrate wafer comprises one of a silicon wafer, a gallium arsenide wafer, and a sapphire wafer.

19. The apparatus of claim 13, wherein the cap wafer comprises one of a silicon wafer, a gallium arsenide wafer, and a glass wafer.

20. The apparatus of claim 13, wherein a side of the substrate wafer opposite a side on which the devices are formed comprises a metallization pattern that is electrically connected to at least some of the electrodes by the through-wafer vias.

21. Apparatus, comprising:
a substrate wafer having i) a device formed thereon, and ii) at least one through-wafer via positioned to coincide with an electrode of the device;
a separation wall on the substrate wafer, around the device; and
a cap wafer, wafer-bonded to the separation wall on the substrate wafer, to hermetically seal the device between the substrate wafer and the cap wafer, the cap wafer having no vias therein for connecting to the device.
